(19) United States
(12) Patent Application Publication
(10) Pub. No.: US 2024/0414996 A1
(43) Pub. Date: Dec. 12, 2024

(54) TRANSPARENT DISPLAY DEVICE

(71) Applicant: Japan Display Inc., Tokyo (JP)

(72) Inventors: Kenichi TAKEMASA, Tokyo (JP); Daiki ISONO, Tokyo (JP)

(21) Appl. No.: 18/677,977

(22) Filed: May 30, 2024

(30) Foreign Application Priority Data
Jun. 8, 2023 (JP) 2023-094892

(51) Int. Cl. H10K 59/80; H10K 59/131

(52) U.S. Cl. CPC H10K 59/8794; H10K 59/131; H10K 59/8722

(57) ABSTRACT

The following transparent display device is used: an array substrate having a translucency, including a first main surface and a second main surface opposite to the first main surface, and having a display unit; a transparent substrate having a transparency and including a third main surface and a fourth main surface opposite to the third main surface; a plurality of sealing materials connecting the second main surface and the third main surface to each other in a plan view; an opening defining an inlet for a cooling medium having translucency; an opening defining an outlet for the cooling medium; and a flow path surrounded by the array substrate, the transparent substrate, and the plurality of sealing medium, and the cooling medium flows through the flow path from one of the openings 8 to the other of the openings.

### CROSS-REFERENCE TO RELATED APPLICATION

The present application claims priority from Japanese Patent Application No. 2023-094892 filed on Jun. 8, 2023, the disclosure of which is incorporated herein by reference.

### TECHNICAL FIELD OF THE INVENTION

The present invention relates to a transparent display device equipped with a cooling mechanism.

### BACKGROUND OF THE INVENTION

There is a transparent display device that is configured by arranging a plurality of fine self-luminous elements (for example, light emitting diodes) on a circuit board with high transmittance. Since such a transparent display device does not use reflection or diffusion, there is little loss of light and high brightness can be achieved.

Patent Document 1 (Japanese Unexamined Patent Publication No. 2003-124671) discloses that a heat dissipation pipe is arranged in a display case of a notebook personal computer on a back side of a display, and the display is cooled by cooling water flowing inside the heat dissipation pipe.

Patent Document 2 (Japanese Unexamined Patent Application Publication No. 2016-119362) discloses that thin metal wires are formed in a grid shape on a back surface of a transparent organic EL panel, and the thin metal wires are covered with a transparent heat dissipation sheet.

### SUMMARY OF THE INVENTION

In performing high-brightness display in a transparent display device in which self-luminous elements are arranged on a substrate, heat generation of the elements themselves and a substrate circuit(s) may become a problem. That is, a decrease in luminous efficiency due to an increase in temperature of the element, occurrence of damage to the element or circuit due to the high temperature, or the like may happen.

As a measure to prevent temperature rise, there is a method of cooling a heat generating portion(s) by using a heat sink or the like. However, in a case of the transparent display device, the heat generating portion is a display portion of the transparent display device. Therefore, a non-transparent heat dissipation mechanism such as a heat sink used for cooling and the like of a CPU (Central Processing Unit) cannot be adopted. An object of the present invention is to improve performance of a transparent display device.

Other objects and novel features will become apparent from the description of this specification and the accompanying drawings.

A brief overview of typical embodiments disclosed in the present application will be as follows.

A transparent display device, which is one embodiment, includes: an array substrate having translucency, including a first main surface and a second main surface opposite to the first main surface, and having a display unit; a transparent substrate having the translucency and including a third main surface and a fourth main surface opposite to the third main surface; a plurality of sealing materials connecting the second main surface and the third main surface to each other in a plan view; a first opening serving as an inlet of a cooling medium; a second opening serving as an outlet of the cooling medium; and a flow path surrounded by the array substrate, the transparent substrate, and the plurality of sealing members, in which the cooling medium has translucency and the flow path connects the first opening and the second opening.

### BRIEF DESCRIPTION OF THE DRAWINGS

FIG. 1 is a schematic perspective view showing a transparent display device according to a first embodiment;

FIG. 2 is a plan view showing an array substrate of the transparent display device according to the first embodiment; FIG. 3 is a plan view showing one pixel of the transparent display device according to the first embodiment;

FIG. 4 is a circuit diagram showing a pixel circuit of the transparent display device according to the first embodiment;

FIG. 5 is a plan view schematically showing a plurality of pixels of the transparent display device according to the first embodiment;

FIG. 6 is a plan view showing a transparent display device according to a second embodiment;

FIG. 7 is a cross-sectional view taken along line A-A in FIG. 6;

FIG. 8 is a cross-sectional view showing a method of manufacturing the transparent display device according to the second embodiment;

FIG. 9 is a cross-sectional view showing the method of manufacturing the transparent display device following FIG. 8;

FIG. 10 is a cross-sectional view showing the method of manufacturing the transparent display device following FIG. 9;

FIG. 11 is a cross-sectional view showing the method of manufacturing the transparent display device according to the first modification example of the second embodiment;

FIG. 12 is a cross-sectional view showing the method of manufacturing the transparent display device following FIG. 11; FIG. 13 is a plan view showing a method of manufacturing a transparent display device according to a second modification example of the second embodiment;

FIG. 14 is a plan view showing the method of manufacturing the transparent display device following FIG. 13;

FIG. 15 is a plan view showing a method of manufacturing a transparent display device according to a comparative example; and

FIG. 16 is a plan view showing the method of manufacturing the transparent display device following FIG. 15.

### DESCRIPTION OF THE PREFERRED EMBODIMENTS

Embodiments of the present invention will be described below with reference to the drawings. Note that the disclosure is merely one example, and any modifications that can be easily made by those skilled in the art while maintaining the gist of the invention are naturally included within the scope of the present invention. In addition, in order to make the explanation clearer, the drawings may schematically represent a width, a thickness, a shape, and the like of each part compared to the actual aspect, but these are only examples and the interpretation of the present invention is not limited. In addition, in this specification and each figure, elements similar to those described above with respect to the existing figures are denoted by the same or related numerals, and detailed explanations may be omitted as appropriate.

A planar shape in this application refers to a shape of an object in a plan view. The plan view here refers to an position relationship when viewing the object from a direction perpendicular to a main surface, which is a particularly large surface of the object.

Furthermore, when it is necessary to explain a certain element by distinguishing it into each color of RGB (red, green, blue), the symbol R, G, or B is added after a code indicating the element to distinguish it. However, if it is not necessary to explain the element separately for each color of RGB, only the reference numeral indicating the element will be used for explanation.

### First Embodiment

### Configuration of Transparent Display Device

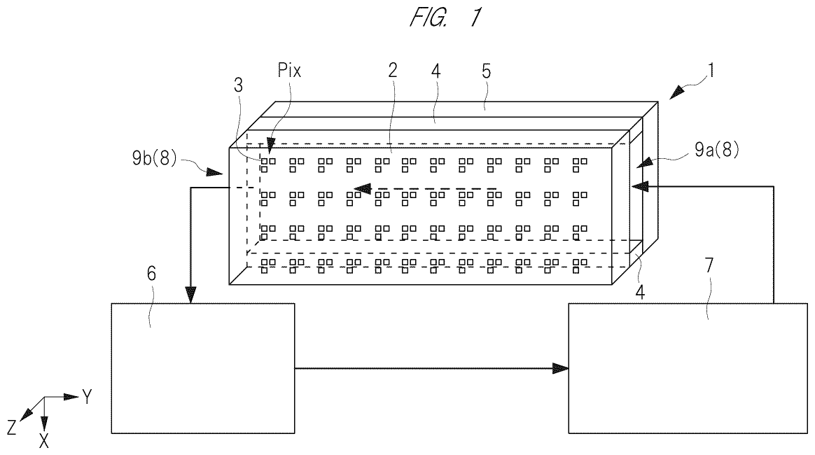

With reference to FIG. 1, a transparent display device 1 according to the present embodiment will be described. FIG. 1 is a schematic perspective view showing a transparent display device according to this embodiment. As shown in FIG. 1, a transparent display device 1 includes an array substrate 2, a transparent substrate 5, and a sealing material 4 that connects the array substrate 2 and the transparent substrate 5 to each other. The array substrate 2 includes a first main surface and a second main surface opposite to the first main surface. Further, the array substrate 2 has a support substrate, and on a main surface of the support substrate, a transistor, a wiring layer including a wiring and an insulating film, and a light emitting element 3 thereon are provided. A plurality of light emitting elements 3 are divided into, for example, a light emitting element 3R that emits red light, a light emitting element 3G that emits green light, and a light emitting element 3B that emits blue light. The three light emitting elements 3R, 3G, and 3B are arranged together and configure one pixel Pix. In other words, one pixel Pix is configured by the three light emitting elements 3R, 3G and 3B. On the main surface of the support substrate, a plurality of such pixels Pix are arranged in a matrix in an X direction and a Y direction. That is, the plurality of light emitting elements 3 are lined up along each of the first main surface and the second main surface of the array substrate 2. The array substrate 2 includes a support substrate, the above-described transistors, wiring layers, and light emitting elements 3. The main surfaces referred to in this application are all along an X-Y plane, and a direction (normal direction) perpendicular to this main surface is a Z direction.

The X direction and the Y direction are directions orthogonal to each other. However, the X direction may not be orthogonal to the Y direction, but may intersect with it. The transparent substrate 5 includes a third main surface and a fourth main surface opposite to the third main surface. The second main surface of the array substrate 2 and the third main surface of the transparent substrate 5 oppose each other in the Z direction which is a direction perpendicular to each of the X direction and the Y direction. That is, the array substrate 2 and the transparent substrate 5 overlap each other in the direction (Z direction) perpendicular to each of the first main surface, the second main surface, the third main surface, and the fourth main surface. There is a space (flow path) in which no solid matter is formed between the array substrate 2 and the transparent substrate 5 that oppose each other, and two sealing materials 4 are formed so as to sandwich the space in the X direction. One of the two sealing materials 4 connects one end portion of the array substrate 2 and one end portion of the transparent substrate 5 in the X direction. The other one of the two sealing materials 4 connects the other end portion of the array substrate 2 and the other end portion of the transparent substrate 5 in the X direction.

Each of the array substrate 2, the sealing material 4, and the transparent substrate 5 extends in the Y direction here. In the plan view, each shape of the array substrate 2 and the transparent substrate 5 is rectangular. However, the array substrate 2 and the transparent substrate 5 may extend in the X direction. Further, each planar shape of the array substrate 2 and the transparent substrate 5 is not limited to a rectangle, but may be a square or the like.

When the transparent display device 1 is viewed from the Y direction, the space is surrounded by the array substrate 2, the sealing material 4, the transparent substrate 5, and the sealing material 4, which are connected in order to form a ring shape. In the plan view, the space extends in the Y direction. That is, the shape of the transparent display device 1 configured by the array substrate 2, the two sealing materials 4, and the transparent substrate 5 is a rectangular cylinder shape having a cavity at its center. The cavity (space) is a flow path through which a cooling medium (liquid or gas) mainly for cooling the array substrate 2 passes. The transparent display device 1 has openings 8 at each of both ends (side surfaces on both sides) in the Y direction. These two openings 8 are connected to each other by a flow path. That is, one opening 8 in the Y direction defines an inlet 9a of the flow path, and the other opening 8 in the Y direction defines an outlet 9b of the flow path. A periphery of each opening 8 is configured by the array substrate 2, the sealing material 4, the transparent substrate 5, and the sealing material 4, which are connected in order to form an annular shape.

The support substrate and the transparent substrate 5 are glass substrates or flexible resin substrates, and both have translucency. As a material of the transparent substrate 5, a transparent material such as glass, acrylic, or sapphire can be used. The transistor is, for example, a TFT (Thin Film Transistor). The array substrate 2 may also be referred to as a TFT substrate, a wiring substrate, or a backplane substrate. Among parts configuring the array substrate 2, the wiring and the light emitting elements 3 may not have translucency, but the insulating film does have translucency. In the plan view, since an area of the wiring and the light emitting element 3 with respect to the first main surface of the array substrate 2 is small, the array substrate 2 as a whole has translucency.

The cooling medium flowing through the flow path may be gas or liquid as long as it has translucency. As gaseous cooling medium, for example dry air or hydrogen gas can be used. For example, water and the like can be used as the liquid cooling medium. The light emitting element 3 is a light emitting diode (LED) having an anode terminal and a cathode terminal. The light emitting element 3 may be, for example, an organic light emitting diode (OLED).

Therefore, the transparent display device 1 containing the cooling medium in the flow path has translucency in the plan view. Therefore, it is visible to an observer who is on a first main surface side of the array substrate 2, for example. An observer can recognize emission light and background light in combination. In this way, the observer using the transparent display panel can also visually recognize a background located on the other side with the transparent display device 1 in between. Furthermore, an image can be displayed on the surface (display panel) of the transparent display device 1 by selectively emitting light from a plurality of pixels Pix lined up on the first main surface side, for example. At this time, the observer can visually recognize the displayed image and the background in a superimposed manner. Note that in order to make the drawing easier to understand, in FIG. 1, an outline of a part of the array substrate 2 hidden by the array substrate 2, as well as outlines of the sealing material 4 and the transparent substrate 5 are shown with broken lines, but illustration by the broken line of an outline of a part of the transparent substrate 5 is omitted.

The sealing material 4 is formed on an outer periphery of the transparent display device 1, and is preferably made of a transparent material in order to enhance the overall translucency of the transparent display device 1. The sealing material 4 is made of a material that does not allow a passage of gas or liquid as a cooling medium.

Although not shown in FIG. 1, a circulation flow path (for example, a pipe) for connection with an outside of the transparent display device 1 is connected to each of the openings 8 of the transparent display device 1 so that the cooling medium is prevented from leaking. The outlet 9b of the path flow of the transparent display device 1 is connected to a pump 6 via the circulation flow path (external flow path). The pump 6 is connected to a cooling unit (cooling mechanism) 7 via the circulation flow path such as a pipe. The cooling unit 7 is connected to the inlet 9a of the flow path of the transparent display device 1 via the circulation flow path. The pump 6 is a fluid machine that circulates (pressures) the cooling medium through the cooling unit 7, the transparent display device 1, and the pump 6 in this order via the circulation flow path. The cooling unit 7 is, for example, a heat sink formed by arranging a plurality of metal plates, or is equipped with a fan that blows air to the heat sink and cools the cooling medium by the heat sink. Moreover, the cooling unit 7 may be a cooler that cools the cooling medium by using a catalyst. In this way, the pump 6 and the cooling unit 7 are provided in the circulation flow path. The circulation flow path circulates the cooling medium from the outlet 9b through the outside of the transparent display device 1 to the inlet 9a.

Here, a configuration in which the pump 6 is connected between the outlet 9b of the transparent display device 1 and the cooling unit 7 has been described, but the pump 6 may be connected between the inlet 9a of the transparent display device 1 and the cooling unit 7.

Since the light emitting elements and the substrate circuits (such as the transistors and wiring described above) that configure the transparent display device 1 generate heat, the transparent display device 1 can be cooled by the cooling medium flowing in contact with the second main surface of the array substrate 2. The cooling medium (for example, air or water) that has removed the heat from the transparent display device 1 is sent out by the pump 6, cooled by the cooling unit 7, and used again to cool the transparent display device 1. In other words, the cooling medium is cooled by the cooling unit 7 while circulating from the outlet 9b through the outside of the transparent display device 1 to the inlet 9a. Since the heat is radiated from the cooling medium in the cooling unit 7, it is possible to prevent the temperature of the cooling medium from continuing to rise and the temperature of the transparent display device 1 from increasing excessively accordingly.

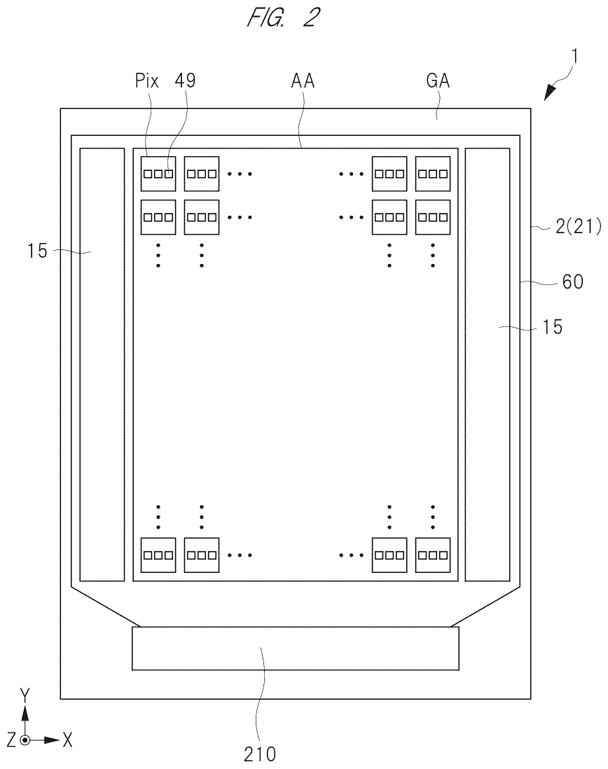

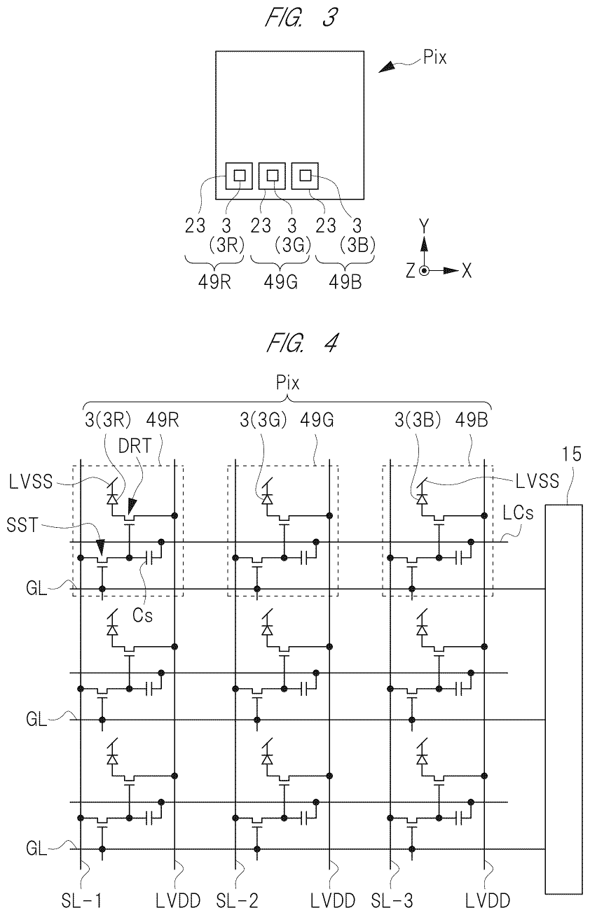

Next, a specific structure of the array substrate 2 will be explained by using FIGS. 2 to 5. FIG. 2 is a plan view showing the array substrate of the transparent display device according to the present embodiment. FIG. 3 is a plan view showing one pixel of the transparent display device according to the present embodiment. FIG. 4 is a circuit diagram showing a pixel circuit of the transparent display device according to the present embodiment. FIG. 5 is a plan view schematically showing a plurality of pixels of the transparent display device according to the present embodiment.

As shown in FIG. 2, the transparent display device 1 includes an array substrate 2, a pixel Pix, a drive circuit 15, a drive IC (Integrated Circuit) 210, and a cathode wiring 60. The array substrate 2 is a drive circuit substrate for driving each pixel Pix, and is also called a backplane or an active matrix substrate. The array substrate 2 includes a support substrate 21, a plurality of transistors, a plurality of capacitors, various wirings, and the like. Although not particularly illustrated, a flexible printed circuit board (FPC) or the like may be connected to the array substrate 2 for inputting control signals and power for driving the drive circuit 15 and the drive IC 210.

As shown in FIG. 2, the transparent display device 1 has a display region AA and a peripheral region GA. The display region AA is a region that is arranged to overlap with the plurality of pixels Pix and displays an image. The peripheral region GA is a region that does not overlap with the plurality of pixels Pix and is arranged outside the display region AA.

The plurality of pixels Pix are arranged in the X direction and the Y direction in the display region AA of the support substrate 21. The X direction and the Y direction are directions parallel to a main surface of the support substrate 21.

The drive circuit 15 is a circuit that drives the plurality of gate lines GL (see FIG. 4) based on the drive IC 210 or various control signals from the outside. The drive circuit 15 selects a plurality of gate lines GL sequentially or simultaneously and supplies a gate drive signal to the selected gate lines GL. Consequently, the drive circuit 15 selects the plurality of pixels Pix connected to the gate line.

The drive IC 210 is a circuit that controls the display of the transparent display device 1. The drive IC 210 is mounted in the peripheral region GA of the support substrate 21 as a COG (Chip On Glass). The present invention is not limited thereto, and the drive IC 210 may be mounted on the flexible printed circuit board or a rigid circuit board connected to the peripheral region GA of the support substrate 21.

The cathode wiring 60 is provided in the peripheral region GA of the support substrate 21. The cathode wiring 60 is provided so as surround the plurality of pixels Pix in the display region AA and the drive circuit 15 in the peripheral region GA. The cathodes of the plurality of light emitting elements 3 are electrically connected to a common cathode wiring 60 and a reference potential (for example, ground potential) is suppled. More specifically, a cathode terminal (not shown) of the light emitting element 3 is connected to the cathode wiring 60 via a cathode electrode (not shown) and a cathode power line LVSS.

As shown in FIG. 3, one pixel Pix includes a plurality of sub-pixels 49. For example, the pixel Pix includes a first sub-pixel 49R, a second sub-pixel 49G, and a third sub-pixel 49B. The first sub-pixel 49R displays primary color red as first color.

The second sub-pixel 49G displays primary color green as second color. The third sub-pixel 49B displays primary color blue as third color. As shown in FIG. 3, in one pixel Pix, the first sub-pixel 49R, the second sub-pixel 49G, and the third sub-pixel 49B are lined up in the X direction. Although FIG. 1 shows a configuration in which the light emitting elements 3 configuring one pixel Pix are arranged in an L-shape, the first sub-pixel 49R, the second sub-pixel 49G, and the third sub-pixel 49B may be arranged in a straight line as shown in FIG. 2. Note that the first color, second color, and third color are not limited to red, green, and blue, respectively, and any color such as complementary color can be selected. In the following, when there is no need to distinguish between the first sub-pixel 49R, the second sub-pixel 49G, and the third sub-pixel 49B, they will be referred to as sub-pixels 49.

The first sub-pixel 49R, the second sub-pixel 49G, and the third sub-pixel 49B each include a light emitting element 3R, a light emitting element 3G, a light emitting element 3B, and an anode electrode 23. The transparent display device 1 displays an image by emitting different light for each of the light emitting elements 3R, 3G, and 3B in the first sub-pixel 49R, the second sub-pixel 49G, and the third sub-pixel 49B. The light emitting element 3R emits red light. The light emitting element 3G emits green light. The light emitting element 3B emits blue light.

The light emitting element 3 is provided in each of the plurality of sub-pixels 49. The light emitting element 3 is an LED chip having a size of approximately 3 μm or more and 300 um or less in the plan view. Although not strictly defined, devices with a chip size of less than 100 μm are called micro LEDs. The transparent display device 1 including the micro LED in each pixel is also called a micro LED display device. Note that the size of the light emitting element 3 is not limited to a size of the micro LED.

Note that the plurality of light emitting elements 3 may emit light of four or more kinds of color. Further, arrangement of the plurality of sub-pixels 49 is not limited to the configuration shown in FIG. 2. For example, the first sub-pixel 49R may be adjacent to the second sub-pixel 49G in the X direction. The first sub-pixel 49R, the second sub-pixel 49G, and the third sub-pixel 49B may be arranged in a triangular lattice shape. Moreover, order of the arrangement of the first sub-pixel 49R, the second sub-pixel 49G, and the third sub-pixel 49B in the X direction may also be different.

FIG. 4 is a circuit diagram showing a pixel circuit. The pixel circuit shown in FIG. 4 is a circuit that is provided on the support substrate 21 and supplies a drive signal (current) to each light emitting element 3. As shown in FIG. 4, the plurality of gate lines GL each extend in the X direction and are connected to the plurality of first sub-pixels 49R, second sub-pixels 49G, and third sub-pixels 49B. A plurality of first signal lines SL-1, second signal lines SL-2, and third signal lines SL-3 each extend in the Y direction. The first signal line SL-1 is connected to the plurality of first sub-pixels 49R arranged in the Y direction. The second signal line SL-2 is connected to the plurality of second sub-pixels 49G arranged in the Y direction. The third signal line SL-3 is connected to the plurality of third sub-pixels 49B arranged in the Y direction. Note that in the following description, unless it is necessary to distinguish between the first signal line SL-1, the second signal line SL-2, and the third signal line SL-3, they will simply be referred to as signal lines SL.

Each sub-pixel 49 includes two transistors and one capacitor. Specifically, each sub-pixel 49 includes a drive transistor DRT, a write transistor SST, and a capacitor Cs.

Each of the plurality of transistors included in each sub-pixel 49 is configure by an n-type TFT. However, the present invention is not limited thereto, and each transistor may be configured by a p-type TFT.

A gate of the drive transistor DRT is connected to a drain of the write transistor SST. A source of drive transistor DRT is connected to an anode power supply line LVDD. The drain of the drive transistor DRT is connected to the anode of the light emitting element 3. The cathode of the light emitting element 3 is connected to the cathode power line LVSS, and a reference potential is supplied thereto.

A gate of the write transistor SST is connected to the gate line GL. A source of the write transistor SST is connected to a signal line SL. A drain of the write transistor SST is connected to the gate of the drive transistor DRT.

One end of the capacitor Cs is connected to the gate of the drive transistor DRT and the drain of the write transistor SST, and the other end is connected to a common wiring LCs. The common line LCs is electrically connected to the cathode power supply line LVSS, and the reference potential is supplied thereto. The capacitor Cs is added to the pixel circuit in order to suppress fluctuations in gate voltage parasitic capacitance and a leakage current of the drive transistor DRT.

The write transistor SST functions as a switching element that selects conduction and non-conduction between two nodes. The drive transistor DRT functions as a current control element that controls a current flowing through the light emitting element 3 according to a voltage between the gate and the drain. Specifically, the drive circuit 15 selects the plurality of gate lines GL and supplies a gate drive signal to the selected gate lines GL. When a potential of the gate line GL becomes a H (high) level due to the gate drive signal, the write transistor SST is turned on. Consequently, charges are accumulated in the capacitor Cs based on a video signal supplied from the signal line SL. The voltage between the gate and the drain of the drive transistor DRT is determined according to an amount of charges in the capacitor Cs.

A current flows through the drive transistor DRT based on an anode power supply potential PVDD supplied from the anode power supply line LVDD. The drive transistor DRT supplies, to the light emitting element 3, a current according to the voltage between the gate and the drain. The light emitting element 3 emits light with a brightness corresponding to this current. Furthermore, even after the write transistor SST is turned off, a current is supplied to the light emitting element 3 from the anode power supply line LVDD via the drive transistor DRT.

Next, a specific example of a configuration of the pixel Pix in the plan view will be described. FIG. 5 is a plan view schematically showing a plurality of pixels. In FIG. 5, eight pixels Pix arranged in 2 rows and 4 columns are shown in an enlarged manner among the plurality of pixels Pix arranged in the display region AA. Specifically, as shown in FIG. 5, pixels Pix (1, 1), Pix (2, 1), Pix (3, 1), and Pix (4, 1) are arranged in the X direction. In addition, pixels Pix (1, 1) and Pix (1, 2) are arranged in the Y direction. Pixels Pix (2, 1) and Pix (2, 2) are arranged in the Y direction. Pixels Pix (3, 1) and Pix (3, 2) are arranged in the Y direction. Pixels Pix (4, 1) and Pix (4, 2) are arranged in the Y direction. Note that unless it is necessary for explaining a distinction among the pixels Pix (1, 1), Pix (2, 1), Pix (3, 1), Pix (4, 1), Pix (1, 2), Pix (2, 2), Pix (3, 2), and Pix (4, 2), if it is not necessary to explain them separately, they will simply be expressed as pixel Pix.

The plurality of pixels Pix include a light emitting element 3R (first sub-pixel 49R), a light emitting element 3G (second sub-pixel 49G), a light emitting element 3B (third sub-pixel 49B), a first signal line SL-1, a second signal line SL-2, a third signal line SL-3, and a gate line GL. The light emitting element 3R is electrically connected to the first signal line SL-1. The light emitting element 3G is electrically connected to the second signal line SL-2. The light emitting element 3B is electrically connected to the third signal line SL-3.

In the present embodiment, the plurality of light emitting elements 3 and the plurality of signal lines SL (signal line group SLG) are collectively arranged close to each other in two pixels Pix adjacent to each other in the X direction. One adjacent pixel Pix and the other adjacent pixel Pix are arranged in an inverted position relationship with an imaginary line parallel to the Y direction serving as an axis of symmetry.

The two pixels Pix adjacent in the X direction (for example, pixel Pix (2, 2) and pixel Pix (3, 2)) are a region surrounded by two signal line groups SLG adjacent to each other in the X direction and two gate lines GL adjacent in the Y direction.

Each of the plurality of pixels Pix has a light-transmissive region CA and a non-light-transmissive region NCA. The light-transmissive region CA is a region where an aperture ratio is 80% or more in a predetermined region. That is, in the light-transmissive region CA, a ratio of such a region as not to overlap with various wirings such as the signal line SL and the gate line GL and with the anode electrode 23 and the like, which are connected to the light emitting element 3, with respect to an area of the predetermined region is 80% or more. The non-transmissive region NCA is a region where an aperture ratio is smaller than 80% in a predetermined region. That is, in the non-light-transmissive region NCA, the ratio of such a region as not to overlap with various wirings such as the signal line SL and gate line GL and with the anode electrode 23 and the like, which are connected to the light emitting element 3, with respect to the area of the predetermined region is 80% or less.

In the transparent display device 1, an area of the transmissive region CA is provided so as to be larger than an area of the non-transmissive region NCA. Therefore, in the pixel Pix where the light emitting element 3 does not emit light, the background on the second main surface side from the first main surface side of the array substrate 2 is visually recognized via the light-transmissive region CA, and the background on the first main surface side from the second main surface side of the array substrate 2 is visually recognized. Then, in the transparent display device 1 of the present embodiment, when a video signal is inputted from the drive IC 210, the light emitting element 3 of the pixel Pix emits light according to the video signal. Then, the image displayed by the pixel Pix is visually recognized together with the background. That is, the transparent display device 1 is a so-called transparent display used by such an aspect that the other side of the display region AA can be seen through.

Next, a specific example of a configuration of each pixel Pix will be described by focusing on the pixel Pix (1, 1) and pixel Pix (2, 1) that are adjacent in the X direction. Here, one side of the X direction (right-side direction in FIG. 5) may be expressed as an +X direction, and the other side of the X direction (left-side direction in FIG. 5) may be expressed as an −X direction. Similarly, one side of the Y direction (upper-side direction in FIG. 5) may be expressed as a +Y direction, and the other side of the Y direction (lower-side direction in FIG. 5) may be expressed as a −Y direction.

A signal line group SLG includes a plurality of signal lines SL adjacent to each other in the X direction. Specifically, three signal lines SL connected to the pixel Pix (1, 1) (first pixel) on the left side of FIG. 5, and three signal lines SL connected to Pix (2, 1) (second pixel) on the right side thereof are arranged adjacent to each other in the X direction, and are formed as a signal line group SLG. That is, the signal line group SLG includes a pair of first signal lines SL-1, a pair of second signal lines SL-2, and a pair of third signal lines SL-3. In the signal line group SLG, the third signal line SL-3, second signal line SL-2, first signal line SL-1, third signal line SL-3, second signal line SL-2, and first signal line SL-1 are arranged in this order in the X direction. Three signal lines SL connected to the pixel Pix (1, 1) on the left side and three signal lines SL connected to the pixel Pix (2, 1) on the right side thereof are arranged in the same arrangement relationship in the X direction. However, the present invention is not limited to this, and the arrangement of the signal line group SLG may be changed appropriately. In one signal line group SLG, the plurality of signal lines SL are arranged at intervals in the X direction.

In each of the plurality of pixels Pix, the light emitting elements 3R, 3G, and 3B are arranged adjacent to each other in the X direction, and are provided near an intersection of the signal line group SLG and the gate line GL. Specifically, in the X direction, the signal line group SLG is provided between the plurality of light emitting elements 3 forming the pixel Pix (1, 1) and the plurality of light emitting elements 3 forming the pixel Pix (2, 1). Further, a gate line GL intersecting the signal line group SLG in the Y direction is provided among the plurality of light emitting elements 3 forming the pixel Pix (1, 1) and the plurality of light emitting elements 3 forming the pixel Pix (2, 1).

The light emitting elements 3R, 3G, and 3B forming the pixel Pix (1, 1) are arranged in order in the X direction. The light emitting elements 3R, 3G, and 3B are arranged adjacent to the signal line group SLG in the X direction (−X direction). Further, the light emitting elements 3R, 3G, and 3B configuring the pixel Pix (1, 1) are arranged adjacent to each other in the −Y direction of the gate line GL intersecting the signal line group SLG.

The light emitting elements 3R, 3G, and 3B configuring the pixel Pix (2, 1) are arranged in order in the X direction, and are arranged adjacent to the signal line group SLG and the X direction (+X direction). Furthermore, the light emitting elements 3R, 3G, and 3B configuring the pixel Pix (2, 1) are arranged adjacent to each other in the +Y direction of the gate line GL. The plurality of light emitting elements 3 of the pixel

Pix (1, 1) and the plurality of light emitting elements 3 of the pixel Pix (2, 1) are arranged in the same arrangement relationship in the X direction. However, the order of arrangement of the plurality of light emitting elements 3 may be different for each pixel Pix.

The light emitting elements 3 are each connected to each signal line SL via the semiconductor layer 71 of the write transistor SST. Further, each of the light emitting elements 3 is electrically connected to the anode power supply line LVDD via a conductive connection portion in a contact hole penetrating through the insulating layer. The anode power line LVDD and the cathode power line LVSS are provided so as to overlap with the gate line GL, and extend in the X direction. Note that in FIG. 5, the anode power line LVDD and the cathode power line LVSS are represented by dash-double-dot lines in order to make the drawing easier to understand. The gate line GL is formed on the support substrate 21, the anode power line LVDD is formed on the gate line GL, and the cathode power line LVSS is formed on the anode power line LVDD. A configurations of pixel Pix (3, 1) and pixel Pix (4, 1) are the same as those of pixel Pix (1, 1) and pixel Pix (2, 1). That is, the plurality of signal lines SL are arranged in a bundle for each two pixels Pix adjacent to each other in the X direction to form the signal line group SLG. Then, the plurality of light emitting elements 3 respectively configuring the two pixels Pix adjacent to each other in the X direction are arranged close to each signal line group SLG. Further, the plurality of light emitting elements 3 of the pixel Pix (2, 1) and the plurality of light emitting elements 3 of the pixel Pix (3, 1) are arranged between the signal line groups SLG adjacent to each other in the X direction.

As explained above, on the array substrate 2, the non-light transmissive region NCA exists, and various wirings such as the signal line SL and the gate line GL as well as the light emitting element 3 and the like are non-light transmissive portions.

### Effects of Present Embodiment

In the transparent display devices, heat generation of the light emitting elements themselves and the circuit boards may become a problem. In particular, in the transparent display device in which the self-luminance element is arranged in each pixel, the self-luminance element generates heat in the entire array substrate, so that reduction in light-emission efficiency due to the rise of the temperature of the light-emission element or the occurrence of the damage and the like to the element (light-emission element, transistors, or the like) or the circuit due to the high temperature is likely to happen. In order to prevent such problems due to the temperature rise, there is a method of cooling the heat generating portion by using the heat sink or the like.

However, since the metal heat sinks are non-transparent, they cannot adopt transparency essential to the transparent display devices. For example, there is also a method of cooling a display panel by flowing a cooling medium such as water through a non-transparent pipe made of metal. However, similarly to the above, cooling the display panel by using non-transparent parts cannot adopted for impairing the translucency of the transparent display devices.

If the heat sink is not provided, measures such as reducing the brightness of the light emitting elements or reducing the density of the light emitting elements that are heat source may be taken to suppress the heat generation. However, in that case, performance such as visibility and resolution of images displayed on the transparent display device deteriorates.

Therefore, in the present embodiment, as shown in FIG. 1, a flow path surrounded by the transparent substrate 5, the sealing material 4, and the array substrate 2 is configured on the second main surface side (back side) of the array substrate 2. By flowing a cooling medium such as water through the flow path, the transparent display device 1 (mainly the array substrate 2) can be cooled. Further, both the array substrate 2 and the transparent substrate 5, which overlap each other in a plan view, have translucency, and the cooling medium flowing through the flow path is also transparent. Therefore, the transparent display device 1 can be cooled without impairing the translucency of the transparent display device 1. Accordingly, it is possible to prevent the decrease in the luminous efficiency of the light emitting element due to the temperature rise and the occurrence of the damage to the element or circuit due to the high temperature. Since the suppression of the temperature rise becomes possible, it is also possible to further enhance the brightness of the light emitting element. As described above, the performance of the transparent display device can be improved.

### Second Embodiment

In the first embodiment described above, a structure in which the cooling medium flows linearly from the right-side inlet to the left-side outlet of the transparent display device has been described. However, there is no need to respectively form the inlet and the outlet of the cooling medium on the pair of side surfaces parallel to each other. For example, the inlet and the outlet may be formed on the same side surface, or may be formed on two mutually perpendicular side surfaces.

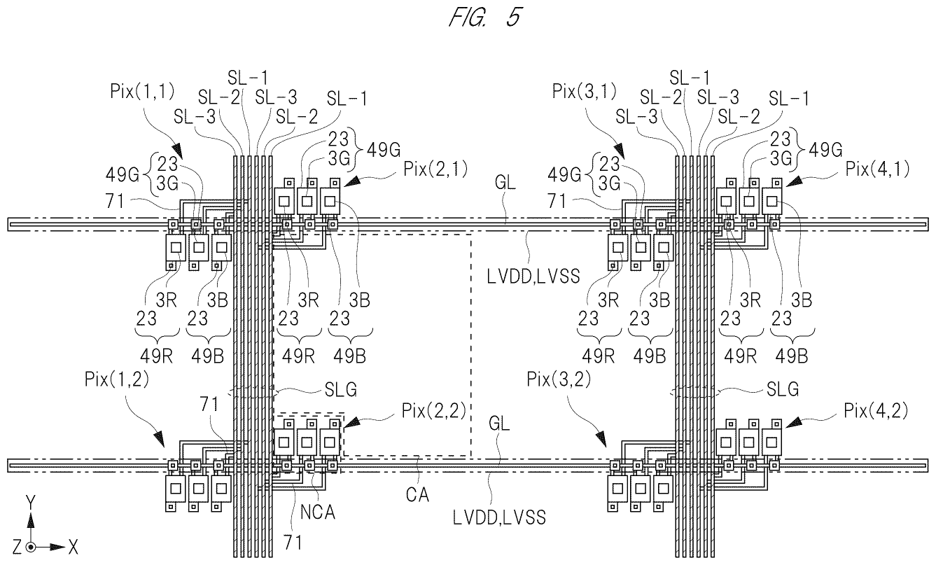

Moreover, the flow path in the transparent display device does not need to be in a straight line. Below, a structure in which a winding flow path is formed by forming a wall made of a transparent material between the array substrate and the transparent substrate will be described by using FIGS. 6 and 7.

FIG. 6 is a plan view showing the transparent display device according to the present embodiment. FIG. 7 is a cross-sectional view taken along line A-A in FIG. 6. In FIG. 6 and FIGS. 14 and 16 used in the following description, the sealing material 4 is hatched to make the drawings easier to understand.

As shown in FIGS. 6 and 7, in addition to the sealing material 4, the present embodiment has a plurality of connection (plate materials, wall materials, flow path forming portions portions) 10 made of transparent materials between the array substrate 2 and the transparent substrate 5. The array substrate 2 and the transparent substrate 5 are connected by the connection portion 10. That is, the connection portion 10 and the sealing material 4 contact with the second main surface 12 of the array substrate 2 and the third main surface 13 of the transparent substrate 5. In other words, the connection portion 10 and the sealing material 4 are formed between the array substrate 2 and the transparent substrate 5. The connection portion 10 is made of a translucent material, and PDMS (dimethylpolysiloxane), which is a type of silicone, can be used as such a material.

The connection portion 10 has a plate-like shape and is provided as a wall that separates the flow path from other flow paths. A shape (layout) of the connection portion 10 in the plan view can be selected from various shapes such as a straight line, an L-shape having a portion bent at 90 degrees, or a curved shape. In FIG. 6, one end (portion) of both the L-shaped connection portion 10 and the linear connection portion 10 in the plan view contacts with the sealing material 4 at an outer periphery portion of the transparent display device la. This is for the following reason: since the connection portion 10 is separated from the sealing material 4, a region in which the cooling medium hardly flows in a space between the array substrate 2 and the transparent substrate 5 occurs and variations in the temperature of the transparent display device la are prevented from occurring.

As shown in FIG. 7, since the connection portion 10 is pressed against the second main surface 12 of the array substrate 2, an end portion on the array substrate 2 side in the Z direction is deformed so as to spread in a lateral direction along a X-Y plane. The connection portions 10 are separated from each other, and a flow path is formed between them. Here, the sealing material 4 covers not only a portion of the second main surface 12 of the array substrate 2 and a portion of the third main surface 13 of the transparent substrate 5, but also the side surface in the direction along the X-Y plane of each of the array substrate 2 and the transparent substrate 5. However, the sealing material 4 may not cover such a side surface. Further, the portion of the sealing material 4 may cover the outer peripheral portion of the first main surface 11 of the array substrate 2 or the outer peripheral portion of the fourth main surface 14 of the transparent substrate 5.

Since the connection portion 10 is formed between the array substrate 2 and the transparent substrate 5, the flow path is bent once or more times between the inlet 9a and the outlet 9b, and the cooling medium flows along such a flow path. In FIG. 6, the inlet 9a and the outlet 9b are formed on one side surface of the transparent display device la in the X direction. As shown by arrows in FIG. 6, the cooling medium that enters the transparent display device la from the inlet 9a flows in the −Y direction, +X direction, +Y direction, +X direction, −Y direction, and −X direction in order, and flows to the outside of the transparent display device la to the outlet 9b. Here, the transparent display device la has the flow path flowing in a first direction and the flow path flowing in a direction different from the first direction, and these flow paths are separated from each other by the transparent connection portion 10. That is, the connection portion 10 defines a flow path.

Although the connection portion 10 is made of a transparent material, the translucency of the transparent display device 1a may be impaired if the observer is visible. Therefore, in the plan view, the connection portion 10 is arranged to overlap with the non-light transmitting portion (for example, various wirings such as signal lines SL and gate lines GL) shown in FIG. 5, and the connection portion 10 and such portions may extend in the same direction in mutually overlapped regions. Consequently, it is possible to suppress the decrease in translucency of the transparent display device la due to the provision of the connection portion 10.

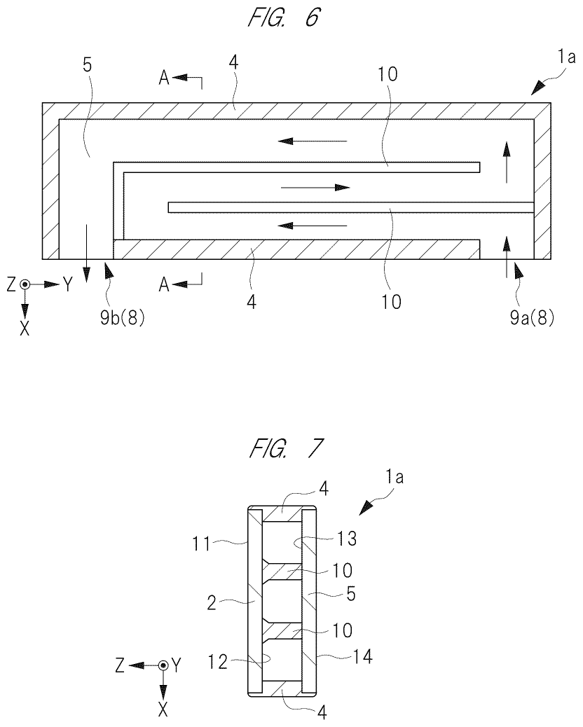

Next, a method of manufacturing the transparent display device of the present embodiment will be described by using cross-sectional views of FIGS. 8 to 10.

First, as shown in FIG. 8, an array substrate 2 and a transparent substrate 5 are prepared. The array substrate 2 has the pixel circuit and the light emitting element on the support substrate. The transparent substrate 5 includes the plurality of connection portions 10 connected on the third main surface 13. The connection portion 10 can be formed, for example, by placing a mold in close contact with the third main surface 13 of the transparent substrate 5 and pouring, for example, liquid PDMS into a cavity of the mold. The connection portion 10 may be formed on the second main surface 12 of the array substrate 2 instead of the transparent substrate 5. A cross-sectional shape of the connection portion 10 is rectangular (for example, oblong).

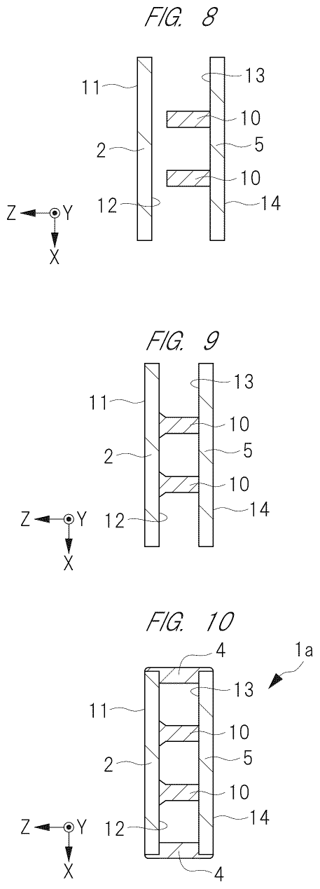

Next, as shown in FIG. 9, the array substrate 2 and the transparent substrate 5 are pressed against each other with the second main surface 12 of the array substrate 2 and the third main surface 13 of the transparent substrate 5 opposing each other. By pressing the array substrate 2 and the transparent substrate 5 against each other, the connection portion 10 between the array substrate 2 and the transparent substrate 5 is brought into close contact with both the array substrate 2 and the transparent substrate 5. At this time, the connection portion 10 has flexibility and is deformed by being pressed against the array substrate 2. Consequently, in the direction along the X-Y plane, a width of an end portion on the array substrate 2 side becomes wider than a width of an end portion on the transparent substrate 5 side. The fact that the connection portion 10 is thus deformed and its cross-sectional shape is no longer rectangular means that the connection portion 10 is in close contact with the array substrate 2 and the transparent substrate 5.

Next, as shown in FIG. 10, while the connection portion 10 contacts with both the array substrate 2 and the transparent substrate 5, a sealing material 4 contacting with both the respective end portions of the array substrate 2 and the transparent substrate 5 in the direction along the X-Y plane is formed. The sealing material 4 is formed near the outer peripheral portion of each of the array substrate 2 and the transparent substrate 5 in the plan view. However, by providing a portion in which the sealing material 4 is not formed on the outer periphery portion of each of the array substrate 2 and the transparent substrate 5, the two openings 8, which are the inlet 9a and the outlet 9b described by using FIG. 6, are formed. By forming the sealing material 4, the array substrate 2 and the transparent substrate 5 are fixed to each other, and the transparent display device la is substantially completed.

The sealing material 4 can be formed, for example, by curing the liquid sealing material 4. The sealing material 4 is formed, for example, with the array substrate 2 and the transparent substrate 5 pressed against each other, and the sealing material 4 is then cured. Consequently, the connection portion 10 can be maintained in close contact with both the array substrate 2 and the transparent substrate 5. By bringing the connection portion 10 into close contact with the array substrate 2 and the transparent substrate 5, leakage of the cooling medium from a gap between the connection portion 10 and the array substrate 2 or the transparent substrate 5 can be prevented.

Here, the sealing material 4 covers not only to the portion of the second main surface 12 of the array substrate 2 and the portion of the third main surface 13 of the transparent substrate 5, but also the side surface in the direction along the X-Y plane of each of the array substrate 2 and the transparent substrate 5. However, the sealing material 4 may not cover the side surface(s). Further, the portion of the sealing material 4 may cover the outer peripheral portion of the first main surface 11 of the array substrate 2 or the outer peripheral portion of the fourth main surface 14 of the array substrate 2.

### Effects of Present Embodiment

In the present embodiment, by providing the connection portion 10, the flow path can be formed in a complicated pattern folded in the plan view. This allows the cooling medium to flow evenly over the entire second main surface 12 of the array substrate 2. That is, since an unintentional difference in the flow of the cooling medium is prevented from occurring between a predetermined region and other regions of the second main surface 12, variations in the cooling effect is prevented from occurring. That is, the cooling efficiency can be improved.

Moreover, a degree of freedom in forming positions of the inlet 9a and the outlet 9b of the cooling medium is increased, and design becomes easier. An aesthetic aspect of the transparent display device may be impaired if an opaque portion (frame) is provided next to the display panel. Therefore, it may be preferable that the inlet 9a and the outlet 9b of the cooling medium are concentrated on one side surface of the transparent display device la in the plan view.

Furthermore, a flow path having a narrow width and a flow path having a wide width in a direction perpendicular to a direction in which the cooling medium flows may be separately created. In this case, the cooling medium flows at a higher speed in the narrow width flow path than in the wide width flow path. This makes it possible to strongly cool locations that are particularly susceptible of high temperatures and to intentionally weaken the cooling effect of locations where temperature is difficult to rise. Accordingly, the local temperature rise is prevented, and the overall temperature of the transparent display device 1 is kept constant. That is, it is possible to prevent variations in the temperature of the transparent display device 1 from occurring.

### First Modification Example

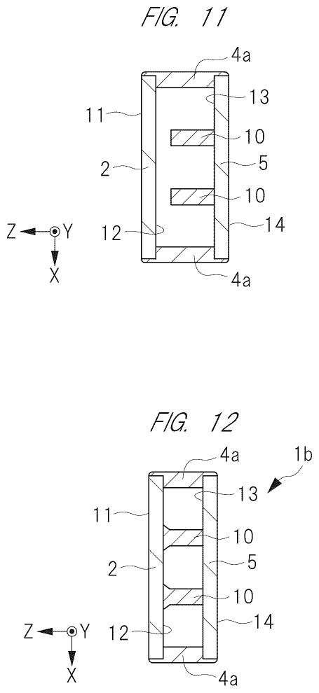

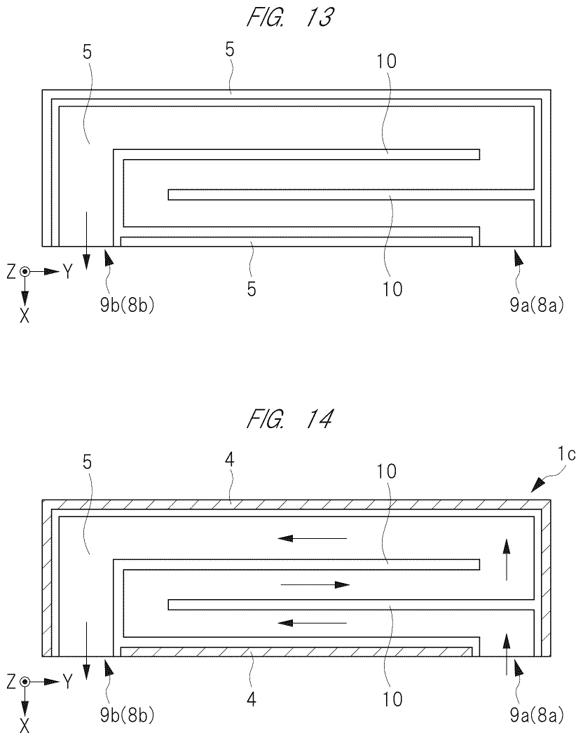

A first modification example of the present embodiment will be described by using FIGS. 11 and 12.

In FIGS. 8 to 10, while the connection portion 10 contacts with both the array substrate 2 and the transparent substrate 5, forming the sealing material 4 has been described. However, even if the connection portion 10 does not contact with one of those substrates, the connection portion 10 may be caused to closely contact with the one substrate by utilizing contraction when the sealing material hardens.

In this modification example, first, as explained by using FIG. 8, the connection portion 10 contacting with the array substrate 2, the transparent substrate 5, and one of them is prepared.

Next, as shown in FIG. 11, the sealing material 4a, which contacts with the respective end portions of the array substrate 2 and the transparent substrate 5 in the direction along the X-Y plane, is formed. At this time, the connection portion 10 may contact with one of the array substrate 2 and the transparent substrate 5, but may be separated from the one substrate. The sealing material 4a is made of a material that has a high shrinkage rate in hardening from a liquid state to a solid state.

Next, as shown in FIG. 12, the sealing material 4a is cured to form the transparent display device 1b of this modification example. At this time, a length of the sealing material 4a in the Z direction becomes shorter due to the contraction during the curing. This applies a force that causes the array substrate 2 and the transparent substrate 5 to approach each other, so that the connection portion 10 closely contacts with both the array substrate 2 and the transparent substrate 5. By causing the connection portion 10 to closely contact with the array substrate 2 and the transparent substrate 5, the cooling medium can be prevented from leaking from the gap between the connection portion 10 and the array substrate 2 or transparent substrate 5.

By utilizing the shrinkage of the sealing material 4a in this way to form the transparent display device 1b, a process of pressing the array substrate 2 and the transparent substrate 5 against each other and a device(s) for the process become unnecessary as explained by using FIG. 9, and the manufacturing process of the transparent display device 1b is simplified. Accordingly, manufacturing cost of the transparent display device 1b can be reduced.

### Second Modification Example

Hereinafter, a case where the connection portion is also formed on the outer periphery portion of the display panel will be described by using FIGS. 13 and 14.

Here, as a comparative example, the following case will be described: after forming the connection portion between the array substrate and the transparent substrate, the sealing material is formed to form the flow path having the sealing material and the connection portion as walls.

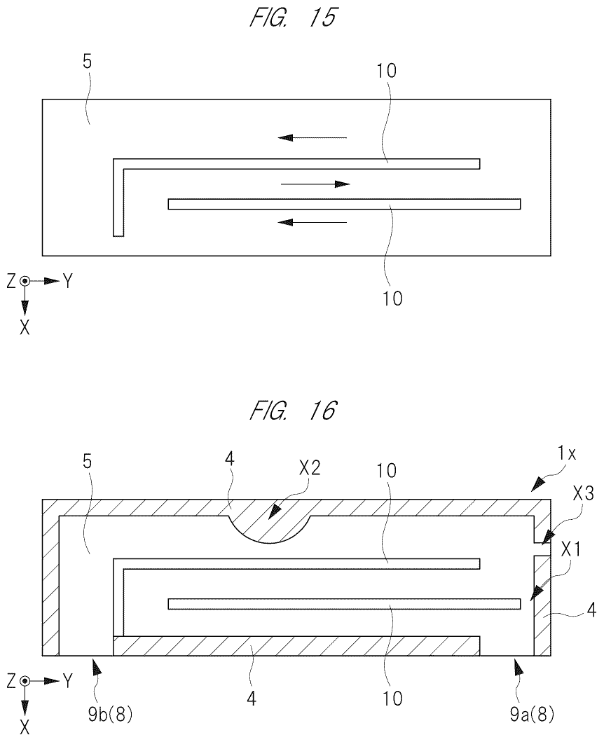

In the comparative example, first as shown in FIG. 15, the connection portion 10 is formed on the third main surface of the transparent substrate 5. The one or more connection portions 10 formed here do not include those forming the outermost wall of the flow path in the transparent display device to be completed later.

Next, as shown in FIG. 16, the array substrate 2 (not shown) and the transparent substrate 5 are opposed to each other and pressed against each other to closely contact the connection portion 10 with the array substrate 2 and, in this state, the sealing material 4 is formed. Consequently, a transparent display device 1x is formed.

At this time, as shown in a defect X1, there is a possibility that the sealing material 4 forming the wall of the flow path and the connection portion 10 may be unintentionally separated. In such a defect X1, if there is not enough sealing material 4, if viscosity of the sealing material 4 is insufficient, if the viscosity of the sealing material 4 is excessively high and it flows, or the like, lack of a place(s) to be sealed occurs. When such a gap occurs, an unplanned flow path is formed, which makis it difficult for the cooling medium to flow through the original flow path and making it impossible to obtain a sufficient cooling effect.

In addition, as shown in a defect X2, there is a possibility that the sealing material 4 may enter into the location where the sealing material 4 is unnecessary. Such a defect X2 occurs when an amount of sealing material 4 is large, when the viscosity of the sealing material 4 is low, or the like. The excessive entrance of the sealing material 4 into the flow path can bring the following problems: the flow path becomes narrow and the flow of the cooling medium is obstructed; a part of the array substrate 2 cannot be cooled; the flow path is blocked; or the like.

Further, as shown in a defect X3, an opening in the sealing material 4 may be formed at a place that is neither the inlet 9a nor the outlet 9b. Such a defect X3 may occur for the same reason as that of the defect X1. If the opening like the defect X3 exists, the flow path is not sealed and a release portion exists, so that the cooling medium leaks out and the sufficient cooling effect is not obtained.

Therefore, in this modification example, first, as shown in FIG. 13, the connection portion 10 is formed on the third main surface of the transparent substrate 5. The one or more connection portions 10 formed here include those forming the outermost wall of the flow path in the transparent display device to be completed later. That is, in the plan view, the connection portion 10 is a portion formed along the outer periphery portion of the transparent substrate 5 or the array substrate 2, and has portions including at least two openings 8a, 8b corresponding to the inlet 9a and the outlet 9b, respectively. The connection portion 10 also includes a portion(s) that is located inside and is surrounded by such portions formed along the outer periphery portions of the transparent substrate 5 or the array substrate 2 in the plan view, and these portions contact with each other. Next, as shown in FIG. 14, the array substrate 2 (not shown) and the transparent substrate 5 are opposed to each other and pressed against each other to closely contact the connection portion 10 with the array substrate 2 and, in this state, the sealing material 4 is formed. In this way, the transparent display device 1c is formed. Note that, as in the first modification example, the connection portion 10 may closely contact with the array substrate 2 and the transparent substrate 5 by utilizing a shrinkage of the sealing material 4 at the time of hardening the sealing material 4. Thus, the transparent display device 1c of the first modification example is formed.

Here, the sealing material 4 is formed outside the connection portion 10, which is a portion formed along the outer periphery portion of the transparent substrate 5 or the array substrate 2 in the plan view. In other words, the sealing material 4 is formed on each end portion side of the transparent substrate 5 or the array substrate 2 rather than the connection portion 10 which is the portion formed along the outer periphery portion of the transparent substrate 5 or the array substrate 2, in the plan view. In other words, all the walls configuring the flow path of the transparent display device 1c are configured by the connection portions 10. In this case, the sealing material 4 is used to fix the array substrate 2 and the transparent substrate 5 to each other, and is not used to form the flow paths. Therefore, the sealing material 4 does not contact with the cooling medium.

In the plan view, the sealing material 4 continuously contacts with the connection portion 10 along the outer periphery portion of the transparent substrate 5 or the array substrate 2. The connection portion 10 is the portion formed along the outer periphery portion of the transparent substrate 5 or the array substrate 2, and includes the openings 8a, 8b corresponding to the inlet 9a and the outlet 9b.

Consequently, the defect X1 in which a gap occurs in the flow path due to a reason such as the insufficient sealing material 4 is not generated. In addition, the defect X2 in which the sealing member 4 enters into the flow path due to a reason such as the too much sealing member 4 does not occur. Further, the defect X3 in which the opening occurs in the flow path due to a reason such as the insufficient sealing material 4 is not generated. Therefore, in this modification example, the decrease in the cooling effect is prevented.

Although the embodiments and the typical modification examples have been described above, the above-described technique can be applied to various modification examples other than the illustrated modification examples. For example, in the first and second embodiments described above, a case where the light emitting element 3 is the LED or the OLED has been described, but the display panel of this embodiment may be the liquid crystal panel, which has a liquid crystal layer, on the array substrate. In that case, a light source is installed, for example, on a side surface side of the display panel (outside in the X or Y direction), and the light source irradiates the liquid crystal layer with light. At this time, the cooling medium cools the transparent display device by removing heat conducted from the light source to the display panel or heat generated from the pixel circuit.

In a category of an idea of the present invention, those skilled in the art can arrive at various modified examples and corrected examples, and it is understood that those modified examples and corrected examples also fall within the scope of the present invention. For example, as long as with respect to the above-mentioned embodiments, addition, deletion, or design change to, from, or of components or by addition, deletion, or condition change to, from, or of step(s) which is appropriately made by those skilled in the art has the gist of the present invention, they also fall within the scope of the present invention.

The present invention can be used for manufacturing light emitting devices.

What is claimed is:

1. A transparent display device comprising:
an array substrate having translucency, including a first main surface and a second main surface opposite to the first main surface, and having a display unit;
a transparent substrate having the translucency and including a third main surface and a fourth main surface opposite to the third main surface;
a plurality of sealing materials connecting the second main surface and the third main surface to each other in a direction perpendicular to the first main surface;
a first opening serving as an inlet of a cooling medium;
a second opening serving as an outlet of the cooling medium; and
a flow path surrounded by the array substrate, the transparent substrate, and the plurality of sealing members,
wherein the cooling medium has translucency, and
whether the flow path connects the first opening and the second opening.

2. The transparent display device according to claim 1,
wherein the cooling medium flows in contact with the second main surface of the array substrate.

3. The transparent display device according to claim 1, further comprising a connection portion having translucency and connecting the second main surface and the third main surface to each other,
wherein the connection portion defines the flow path.

4. The transparent display device according to claim 1,
wherein the display unit of the array substrate is configured by a support substrate and a plurality of light emitting elements formed on the support substrate and arranged along the first main surface of the array substrate.

5. The transparent display device according to claim 4,
wherein each of the plurality of light emitting elements is a light emitting diode or an organic light emitting diode,

6. The transparent display device according to claim 3,
wherein the array substrate includes a support substrate, a plurality of wirings formed on the support substrate, and a plurality of light emitting elements arranged along the first main surface of the array substrate, and
wherein in a plan view, some of the plurality of wirings and the connection portion extend in the same direction in a region where they overlap with each other,

7. The transparent display device according to claim 1, further comprising:
a circulation flow path circulating the cooling medium from the second opening through an outside of the transparent display device to the first opening; and
a cooling unit provided in the circulation flow path.
